(19) United States
(12) Patent Application Publication
(10) Pub. No.: US 2026/0147036 A1
(43) Pub. Date: May 28, 2026

(54) TEST AND/OR MEASUREMENT SYSTEM FOR TESTING A DEVICE-UNDER-TEST

(71) Applicant: Rohde & Schwarz GmbH & Co. KG, Munich (DE)

(72) Inventor: Markus FREIDHOF, Kirchseeon (DE)

(21) Appl. No.: 18/957,101

(22) Filed: Nov. 22, 2024

(51) Int. Cl. G01R 31/3167; H03M 1/10

(52) U.S. Cl. CPC G01R 31/3167; H03M 1/1071

(57) ABSTRACT

The present disclosure relates to a test and/or measurement system for testing a DUT. The test and/or measurement system comprises a first port and a second port, wherein the DUT is connectable between the first and the second port; a signal generator which is configured to generate a digital test signal; a DAC which is configured to convert the digital test signal to an analog test signal; wherein the first port is configured to forward the analog test signal to the DUT, and wherein the second port is configured to receive an analog response signal from the DUT; an ADC which is configured to convert the analog response signal to a digital response signal; and a measurement device which is configured to compare the digital response signal to the digital test signal or to information about the digital test signal; wherein the measurement device is configured to trigger an adaption of an amplitude of the digital test signal based on a result of said comparison.

### TECHNICAL FIELD

The present disclosure relates to a test and/or measurement system for testing a device-under-test, such as a power amplifier for telecommunication signals.

### BACKGROUND ART

When conducting a component test with a power amplifier, a certain target output power of the amplifier is often set prior to starting an actual measurement. The setting of the target output power can be done with a so-called power servoing routine. Once the target output power has been set, the measurements (e.g. recording of the output signal and subsequent calculation of an error vector magnitude, EVM) are carried out. The duration of the power servoing, which precedes these measurements, increases the overall time required to carry out the component test.

It is known to carry out power servoing in an iterative way by providing an input signal to the amplifier, measuring the output power of the amplifier, subsequently setting a new power for the input signal, and repeating the output power measurement with the new input signal. Due to the non-linear property of many amplifiers, several iterations of this procedure might be necessary until a target output power is set.

An additional difficulty may arise if the power servoing (and the subsequent measurements) is carried out with a modulated signal, e.g., a 5th generation mobile communication (new radio) signal. Due to the modulation of the signal, it can take additional time to determine the power of the signal after passing the amplifier, especially because the power at the input of the amplifier is not known. This additionally enhances the required measurement time.

Accordingly, there is a need to provide an improved test and/or measurement system which avoids avoid the above-mentioned limitations and disadvantages.

### SUMMARY

According to an aspect, the disclosure relates to a test and/or measurement system for testing a device-under-test (DUT). The test and/or measurement system comprises: a first port and a second port, wherein the DUT is connectable between the first and the second port; a signal generator which is configured to generate a digital test signal; a digital-to-analog converter (DAC) which is configured to convert the digital test signal to an analog test signal; wherein the first port is configured to forward the analog test signal to the DUT, and wherein the second port is configured to receive an analog response signal from the DUT; an analog-to-digital converter (ADC) which is configured to convert the analog response signal to a digital response signal; and a measurement device which is configured to compare the digital response signal to the digital test signal or to information about the digital test signal; wherein the measurement device is configured to trigger an adaption of an amplitude of the digital test signal based on a result of said comparison.

This achieves the advantage the test and/or measurement system can perform a power servoing with the DUT (e.g., a power amplifier) based on a relative measurement (i.e., a comparison of the digital test signal and the digital response signal). The relative measurement allows for a much faster adaption of the test signal in case of a non-linear behavior of the DUT. In this way, the time required for the power servoing and thus the overall measurement time of a component test with the DUT can be reduced.

The DUT can be a power amplifier, in particular an amplifier for amplifying a power level of a modulated signal, e.g. a signal according to a WiFi, an LTE or a 5G standard.

The measurement device can be configured to adapt the amplitude of the digital test signal based on the comparison result. Alternatively, the measurement device can control a different device of the system, e.g. the signal generator or a control unit, to adapt the amplitude of the digital test signal.

The measurement device can compare a power level of the digital response signal with a measured power level of the digital test signal or with information about a power level of the digital test signal (e.g., extracted from a data file). For instance, the power levels of the digital test signal and the digital response signal are continuously measured and compared by the measurement device such that the amplitude of the digital test signal can be continuously adapted.

In an implementation form, the test and/or measurement system further comprises: a first analog frontend which is connected between the DAC and the first port, and which is configured to amplify the analog test signal; and/or a second analog frontend which is connected between the second port and the ADC.

In an implementation form, the first analog frontend comprises at least one of the following devices: a mixer, and a filter; and/or the second analog frontend comprises at least one of the following devices: an amplifier, an attenuator, and a mixer. The amplifier can be a linear amplifier (LNA).

In an implementation form, the measurement device comprises a first power measurement unit which is configured to measure a first power level of the digital test signal; and the measurement device comprises a second power measurement unit which is configured to measure a second power level of the digital response signal. For instance, the first and the second power measuring unit are each configured to continuously measure the first respectively the second power level.

In an implementation form, the second power measurement unit is configured to perform the measurement of the second power level offset by a delay time to the measurement of the first power level by the first power measurement unit measuring.

For instance, the delay time is based on the time it takes for the digital test signal to return in the form of the digital response signal. In this way for instance, the adaption of the test signal by the DUT can be efficiently analyze. The measurement device can compare the same signal component in the test signal (prior to the DUT) and in the response signal (after passing the DUT).

In an implementation form, the delay time can be based on a time difference between the measurement of a section in the digital test signal by the first power measurement unit and the measurement of the corresponding section in the digital response signal by the second power measurement unit. The section can be a temporal section of the respective signals.

In an implementation form, the test and/or measurement system comprises a sync line which is connected to a respective sync port of the first and the second power measurement unit, wherein the first power measurement unit is configured to measure the first power level upon receiving a sync signal at its sync port and the second power measurement unit is configured to measure the second power level upon receiving the sync signal at its sync port; and wherein a delay unit is arranged in the sync line in front of the second power measurement unit.

By means of the delay line and the delay unit, the sync signal can be delayed by the delay time before reaching the second power measurement unit.

In an implementation form, the measurement device comprises a comparison unit, wherein the comparison unit is configured to receive the first and the second power level from the first and the second power measurement unit, respectively; wherein the comparison unit is configured to determine a difference between the first and the second power level.

In an implementation form, the test and/or measurement further comprises a control unit which is configured receive the difference between the first and the second power level and to adapt the amplitude of the digital test signal based on said difference. For instance, the control unit provides a linear factor which is multiplied to an amplitude of the digital test signal in order to adapt the test signal.

In an implementation form, the control unit is configured to adapt the amplitude of the digital test signal until said difference deviates from an expected difference by less than a threshold value.

For instance, the difference between the first and the second power level corresponds to a current amplification of the test signal by the DUT. The expected difference can be an expected (or ideal) amplification by the DUT that is to be set for a subsequent measurement. The threshold value can represent a certain tolerance.

In an implementation form, the control unit is configured to adapt the amplitude of the digital test signal until said difference deviates from the expected difference by less than the threshold value for at least a predetermined amount of time. In this way, it can be avoided that an only brief undershooting of the threshold value affects the adaption of the amplitude.

In an implementation form, the first and the second power measurement unit are each configured to continuously record sample values of the digital test signal and the digital response signal, wherein the first and the second power measurement unit are each configured to calculate the respective first and second power level based on N sample values. For example, the first and the second power levels are only calculated if N sample values are present.

In an implementation form, the first power measurement unit and the second power measurement unit are each configured to repeat the calculation of the respective first and second power level after each N sample values with N new sample values. In this way, a blockwise averaging of the power measurements can be done, i.e., every power level can be calculated by averaging over N new sample values.

In an implementation form, the first power measurement unit and the second power measurement unit are each configured to adapt the calculated first and second power level based on the latest M recorded sample values. In this way, a moving average of the first and second power level can be continuously calculated. For instance, M is equal to N or is different to N.

In an implementation form, the comparison unit is configured to determine the difference between the first and the second power level every time a new first and/or second power level is calculated. In this way, the change in the power levels and thus also in the difference between the power levels can be continuously determined until said difference corresponds to an expected difference or deviates from the expected difference by less than the threshold value.

In an implementation form, the first power measurement unit and the second power measurement unit are configured to calculate the first and the second power level in the logarithmic scale, and the comparison unit is configured to calculate the difference between the first and the second power level in the logarithmic scale.

In an implementation form, the control unit is configured to receive the difference between the first and the second power level in the logarithmic; wherein an output of the control unit is transformed from the logarithmic scale to the linear scale. This transformation can be done by the measurement device or the control unit itself. The output of the control unit can be a linear factor which is calculated to the amplitude of the digital test signal.

In an implementation form, the measurement device is a field programmable gate array (FPGA).

In an implementation form, the test and/or measurement system further comprises: a first digital signal processor (DSP) which is arranged between the signal generator and the DAC; and/or a second DSP which is arranged between the ADC and the second power measurement unit.

In an implementation form, the signal generator is configured to generate the digital test signal in form of a modulated signal, such as a WiFi, an LTE or a new radio signal.

### BRIEF DESCRIPTION OF THE DRAWINGS

Exemplary embodiments of the disclosure are now further explained with respect to the drawings by way of example only, and not for limitation. In the drawings:

FIG. 1 shows a schematic diagram of a test and/or measurement system according to an embodiment;

FIG. 2 shows a schematic diagram of a test and/or measurement system according to an embodiment;

FIGS. 3A and 3B compare the recording of sample values using different averaging techniques according to an embodiment; and

FIGS. 4A and 4B show the results of power servoing simulations according to an embodiment.

### DETAILED DESCRIPTIONS OF EMBODIMENTS

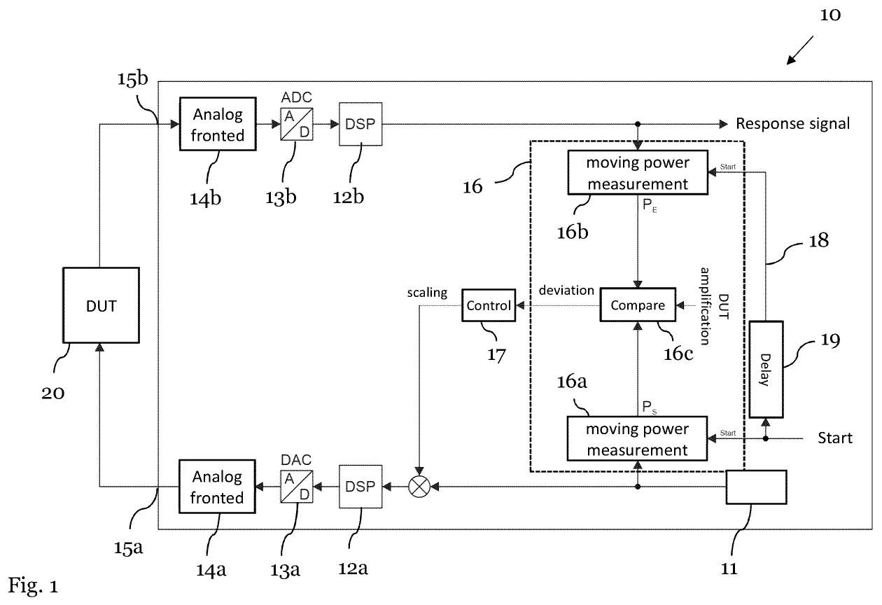

FIG. 1 shows a schematic diagram of a test and/or measurement system 10 for testing a DUT 20 according to an embodiment.

The test and/or measurement system 10 comprises a first port 15a and a second port 15b, wherein the DUT 20 is connectable between the first and the second port 15a, 15b; a signal generator 11 which is configured to generate a digital test signal; a DAC 13a which is configured to convert the digital test signal to an analog test signal; wherein the first port 15a is configured to forward the analog test signal to the DUT 20, and wherein the second port 15n is configured to receive an analog response signal from the DUT 20. The test and/or measurement system 10 further comprises an ADC 13b which is configured to convert the analog response signal to a digital response signal; and a measurement device 16 which is configured to compare the digital response signal to the digital test signal or to information about the digital test signal; wherein the measurement device 16 is configured to trigger an adaption of an amplitude of the digital test signal based on a result of said comparison.

The DUT 20 can be an amplifier, in particular an amplifier for amplifying a power level of a modulated signal, e.g. a signal configured according to a WiFi, an LTE or a 5G standard.

The measurement device 16 can be configured to adapt the amplitude of the digital test signal based on the comparison result. Alternatively, the measurement device can control a different device or unit of the system 10, e.g. the signal generator 11 or a control unit 17, to adapt the amplitude of the digital test signal.

The measurement device 16 can compare a power level of the digital response signal with a measured power level of the digital test signal or with information about a power level of the digital test signal (e.g., extracted from a data file). For instance, the power levels of the digital test signal and the digital response signal are continuously measured and compared by the measurement device such that the amplitude of the digital test signal can be continuously adapted.

The measurement device 16 (which may also be referred to as measurement unit) can be or can comprise a field programmable gate array (FPGA).

The signal generator 11 can be configured to generate the digital test signal in form of a modulated RF signal, such as a WiFi, an LTE or a new radio signal.

The test and/or measurement system 10 can be a single device, wherein at least the signal generator 11, the DAC 13a, the ADC 13b and the measurement device 16 are arranged in the same housing.

The system 10 can further comprise a first analog frontend 14a which is connected between the DAC 13a and the first port 15a and, which is configured to amplify the analog test signal; and/or a second analog frontend 14b which is connected between the ADC 13b and the second port 15b. The first analog frontend 14a may comprise a mixer and/or a filter. The second analog frontend 14b may comprise an amplifier, an attenuator and/or a mixer. For example, the first and the second frontend 14a, 14b are arranged in the same housing as the signal generator 11 and the measurement device 16 or are external devices.

The measurement device 16 may comprise a first power measurement unit 16a and a second power measurement unit 16b. The first power measurement unit 16a can be configured to measure a power level of the digital test signal (in the following: first power level or P_{S}) and the second power measurement unit 16b can be configured to measure a power level of the digital response signal (in the following: second power level or P_{E}).

For instance, the first power measurement unit 16a measures the first power level P_{S} to the test signal continuously (e.g., by performing a moving averaging) and the second power measurement unit 16a measures the second power level P_{E} of the response signal continuously (e.g., by calculating a moving average).

The second power measurement unit 16b can be configured to perform the measurement of the second power level P_{E} offset by a delay time to the measurement of the first power level P_{S}. In this way, it can be ensured that the power measurements of both P_{S} and P_{E} monitor the same temporal section of the respective signals.

For instance, the delay time corresponds to the time the test signal requires to propagate from an input of the first power measurement unit 16a to an input of the second power measurement unit 16b (in the form of the response signal). Thus, the delay time may be based on a time difference between the measurement of a section in the digital test signal by the first power measurement unit 16a and the measurement of the corresponding section in the digital response signal by the second power measurement unit 16b.

The delay of the measurement of the second power level P_{E} can be realized by means of a synchronization (sync) line 18 with a delay unit 19. The sync line 18 can be connected to a respective sync port of the first and the second power measurement unit 16a, 16b. The power measurement units 16a, 16b can measure the respective power levels upon receiving a sync signal via the sync line 18. The delay unit 19 can be arranged in front of the second power measurement unit 16b and can delay the sync signal and thus the measurement of the second power level by the delay time.

The system 10 can compare the first and the second power level P_{E} and P_{S} to an expected amplification by the DUT 20. A deviation to this expected amplification can be determined and by means of a control unit 17, the amplitude of the digital test signal can be adapted (i.e., scaled). This can be realized by means of a comparison unit 16c and a control unit 17.

The comparison unit 16c can be configured to receive the power levels P_{S} and P_{E} from the first and the second power measurement unit 16a, 16b, respectively, and to determine a difference between the power levels P_{S} and P_{E}. The control unit 17 can be configured to receive said difference between the first and the second power level P_{S} and P_{E} and to adapt the amplitude of the digital test signal based on said difference. Measuring and adapting the signals in their digital form has the advantage of being much faster than doing the same with the analog signal.

For instance, the comparison unit 16c (e.g., a comparator) is a component of the measurement device 16 while the control unit 17 is connected to an output of the measurement device 16. However, it also possible that the measurement device 16 comprises both the comparison unit 16 and the control unit 17. The control unit 17 can be a controller, e.g. a proportional integral (PI) controller.

For example, the test and/or measurement system 10 further comprises a first DSP 12a which is arranged between the signal generator 11 and the DAC 13a and/or a second DSP 12b which is arranged between the ADC 13b and the second power measurement unit 16b.

Often, the desired accuracy of the control of the second power level respectively the amplification is specified on a logarithmic scale (dB). Thus, it makes sense to operate the control unit 17 based on logarithmic power levels. Therefore, for instance, the first power measurement unit 16a and the second power measurement unit 16b are configured to calculate the first and the second power level P_{S} and P_{E} in the logarithmic scale, and/or the comparison unit 16c is configured to calculate the difference between the first and the second power level in the logarithmic scale.

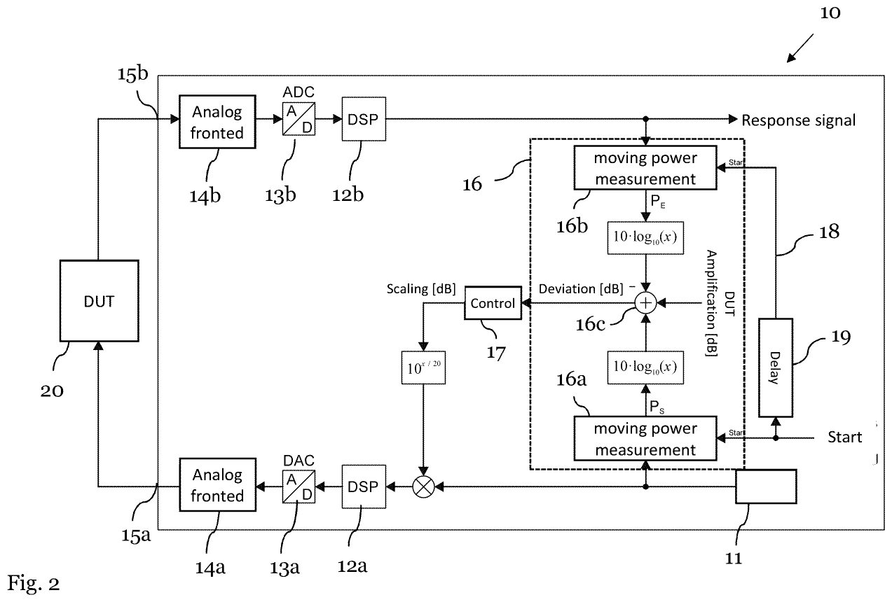

FIG. 2 shows an embodiment of the test and/or measurement system 10 where the power servoing is carried out using such logarithmic measurements and control values. In this system 10, the logarithmic power levels log₁₀(P_{S}) and log₁₀(P_{E}) are determined and compared to an expected amplification of the DUT 20. The resulting deviation can be calculated as follows:

$$Deviation [ dB ] = 10 \cdot {log}_{10} ( {P}_{S} ) - 10 \cdot {log}_{10} ( {P}_{E} ) + Amplification [ dB ] ,$$

Herein, the parameter “Amplification [dB]” is the expected amplification of the DUT 20. The effects of the analog frontends 14a, 14b and/or the DSPs 12a, 12b on the signal leveling can be considered in the expected amplification.

In case the control unit 17 provides its output in a logarithmic scale, this parameter can be converted to a linear factor prior to a multiplication with the amplitude of the digital test signal. This could be done by the measurement unit 16 or by the control unit 17 itself.

The first and the second power level P_{S} and P_{E} can be determined by the measurement device 16 using an averaging technique. Therefore, the first and the second power measurement unit 16a, 16b can be configured to continuously record sample values of the digital test signal and the digital response signal, respectively. Each of the first and the second power level P_{S} and P_{E} can be calculated based on N sample values, e.g., by averaging over the N sample values or a subset thereof.

The averaging over the sample values can be carried out in the form of a blockwise average calculation, a moving average calculation or a combination of both.

In case of a blockwise averaging, the first and the second power measurement units 16a, 16b can be configured to repeat the calculation of the respective first and second power levels after each N sample values with N new sample values. For instance, there is no overlap between the sample values used to calculate each subsequent power level value.

In case of a moving average calculation, the first and the second power measurement unit 16a, 16b can be configured to continuously adjust the calculation of the respective first and second power levels based on the latest N recorded sample values x(k). For such a moving power measurement, the following calculation can be carried out:

$$\hat{P} ( k ) = \frac{1}{N} {\sum }_{i = 0}^{N - 1} {\vert x ( k - i ) \vert}^{2}$$

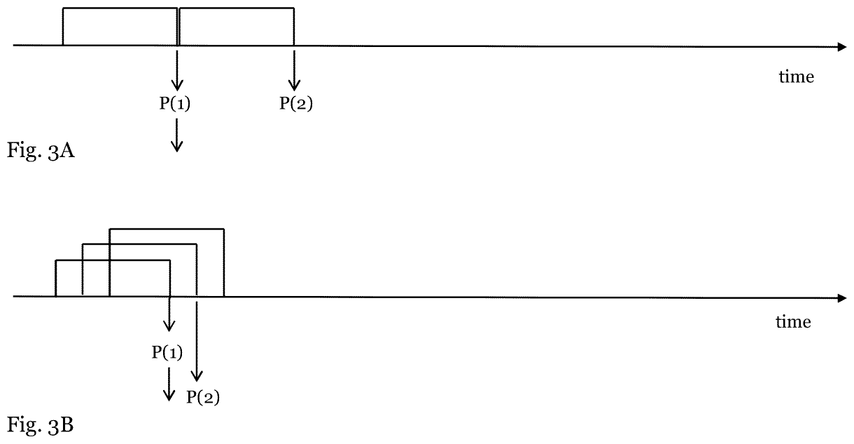

FIGS. 3A and 3B compare the recording of samples P (1, 2, . . . ) using a blockwise (FIG. 3A) to a moving average calculation (FIG. 3B). An advantage of the moving averaging shown in FIG. 3B is that changes caused by a different scaling of the test signal on the response signal can be evaluated more quickly. Typically, there is no gap between measurement intervals of the blockwise averaging.

However, it is typically not necessary to perform a power measurement for every sample, because the sampling values only change marginally between two subsequent recordings. Therefore, a combination of a blockwise and a moving average calculation can be used. For a combined blockwise and moving averaging the following calculations can be carried out:

$$x ( k ) \to y ( l ) = {\sum }_{i = 0}^{{N}_{1} - 1} {\vert x ( l \cdot {N}_{1} + i ) \vert}^{2} \to z ( l ) = {\sum }_{j = 0}^{{N}_{2} - 1} y ( l + j ) \to z ( l )$$

Here, the left equation for calculating y(l) shows the calculation of a blockwise average of a squared magnitude and the right equation for calculating z(l) shows a moving average.

Thus, first an average of N₁ input values (i.e., sample values) x(k) can be calculated. This can be performed for every N₁ input values. The result can then be averaged using a moving average. Thereby, N₂ output values of the blockwise averaging can be averaged. The observation length of the measurement device 16 is then: N=N₁·N₂.

The comparison unit 16c can be configured to determine the difference between the first and the second power level every time a new first and/or second power level is calculated in this way and to forward the result to the control unit 17.

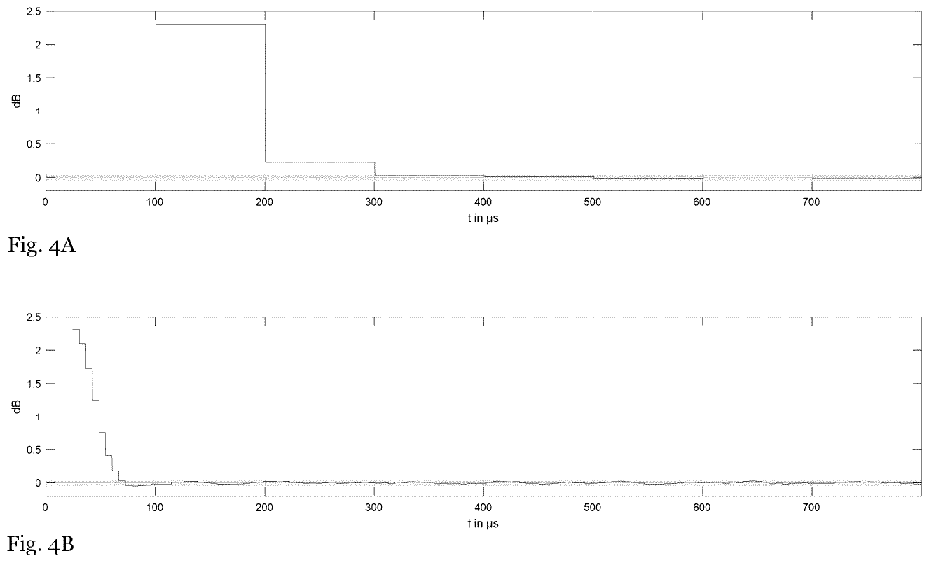

FIGS. 4A and 4B show the results of power servoing simulations according to an embodiment. In particular, FIGS. 4A and 4B compare how long it takes to reach a target amplification, e.g., to deviate from the target amplification by less than a tolerance of 0.05 dB (indicated by the bold gray line). Thereby, FIG. 4A shows a conventional power servoing approach, where only the response signal is measured and FIG. 4B shows a relative measurement as described above (i.e., measuring and comparing both the test signal and the response signal).

The y-axis of the diagrams indicates the deviation in dB between the expected amplification and a current amplification. A new radio signal with a bandwidth of 100 MHz is used as a test signal, wherein the DUT is an amplifier with an amplification error of 2 dB. Typically, when performing conventional power servoing, the power measurement observes the response signal for 200 μs in order to accurately assess the output power level of the DUT with a tolerance of 0.05 dB. This is due to the modulation of the signal which requires long observation times to determine an average signal power. In the example of FIGS. 4A and 4B, the observation time is reduced to 100 μs.

In the conventional approach, shown in FIG. 4A, the test signal is adjusted in steps of 100 μs. After approx. 400-500 μs, it can be assumed that the control is within the 0.05 dB tolerance range.

When performing relative measurements, as shown in FIG. 4B, the observation time of the individual power level measurements can be drastically reduced (here: 24 μs). Every 6 μs a new power level measurement (with overlapping observation times) can be carried out. The control unit 17 can start earlier and the 0.05 dB tolerance range is reached after <100 μs.

In summary, the measurement time required to adjust an output power of a DUT during power servoing can be reduced by: performing (1) relative power measurements and (2) a moving averaging of recorded power samples. During the relative power measurements, the power level of both the test signal and the response signal can be measured for a short observation time. Thereby the runtime of the signal can be compensated in such a way that both measurements observe the same temporal section of the signal. By these simultaneous measurements, amplification fluctuation effects during the power measurement can be compensated and the amplification of the DUT can be determined more quickly. When performing the moving average calculation, the observation times of power level measurements (i.e., recording of sample values) can overlap. In this way, changes in the signal power can be detected earlier and the control unit 17 can quickly react to such changes by adjusting the amplitude of the test signal.

For example, the test and/or measurement system 10 can be configured to carry out various component test measurement with the DUT after a power servoing was carried out. The component test measurements can comprise recording of a response signal from the DUT and subsequently calculating an error vector magnitude (EVM) value. The power servoing can be repeated multiple times during a component test.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A test and/or measurement system for testing a device-under-test, DUT, comprising:
a first port and a second port, wherein the DUT is connectable between the first and the second port;
a signal generator which is configured to generate a digital test signal;
a digital-to-analog converter, DAC, which is configured to convert the digital test signal to an analog test signal;
wherein the first port is configured to forward the analog test signal to the DUT, and wherein the second port is configured to receive an analog response signal from the DUT;
an analog-to-digital converter, ADC, which is configured to convert the analog response signal to a digital response signal; and
a measurement device which is configured to compare the digital response signal to the digital test signal or to information about the digital test signal;
wherein the measurement device is configured to trigger an adaption of an amplitude of the digital test signal based on a result of said comparison.

2. The test and/or measurement system of claim 1, further comprising:
a first analog frontend which is connected between the DAC and the first port, and which is configured to amplify the analog test signal; and/or
a second analog frontend which is connected between the second port and the ADC.

3. The test and/or measurement system of claim 2,
wherein the first analog frontend comprises at least one of the following devices: a mixer, and a filter; and/or
wherein the second analog frontend comprises at least one of the following devices: an amplifier, an attenuator, and a mixer.

4. The test and/or measurement system of claim 1,
wherein the measurement device comprises a first power measurement unit which is configured to measure a first power level of the digital test signal; and
wherein the measurement device comprises a second power measurement unit which is configured to measure a second power level of the digital response signal.

5. The test and/or measurement system of claim 4,
wherein the second power measurement unit is configured to perform the measurement of the second power level offset by a delay time to the measurement of the first power level by the first power measurement unit measuring.

6. The test and/or measurement system of claim 5,
wherein the delay time is based on a time difference between the measurement of a section in the digital test signal by the first power measurement unit and the measurement of the corresponding section in the digital response signal by the second power measurement unit.

7. The test and/or measurement system of claim 4, comprising:
a sync line which is connected to a respective sync port of the first and the second power measurement unit,
wherein the first power measurement unit is configured to measure the first power level upon receiving a sync signal at its sync port and the second power measurement unit is configured to measure the second power level upon receiving the sync signal at its sync port;
wherein a delay unit is arranged in the sync line in front of the second power measurement unit.

8. The test and/or measurement system of claim 4,
wherein the measurement device comprises a comparison unit, wherein the comparison unit is configured to receive the first and the second power level from the first and the second power measurement unit, respectively;
wherein the comparison unit is configured to determine a difference between the first and the second power level.

9. The test and/or measurement system of claim 8, further comprising:
a control unit which is configured receive the difference between the first and the second power level and to adapt the amplitude of the digital test signal based on said difference.

10. The test and/or measurement system of claim 9,
wherein the control unit is configured to adapt the amplitude of the digital test signal until said difference deviates from an expected difference by less than a threshold value.

11. The test and/or measurement system of claim 10,
wherein the control unit is configured to adapt the amplitude of the digital test signal until said difference deviates from the expected difference by less than the threshold value for at least a predetermined amount of time.

12. The test and/or measurement system of claim 4,
wherein the first and the second power measurement unit are each configured to continuously record sample values of the digital test signal and the digital response signal,
wherein the first and the second power measurement unit are each configured to calculate the respective first and second power level based on N sample values.

13. The test and/or measurement system of claim 12,
wherein the first power measurement unit and the second power measurement unit are each configured to repeat the calculation of the respective first and second power level after each N sample values with N new sample values.

14. The test and/or measurement system of claim 12,
wherein the first power measurement unit and the second power measurement unit are each configured to adapt the calculated first and second power level based on the latest M recorded sample values.

15. The test and/or measurement system of claim 8,
wherein the comparison unit is configured to subsequently determine the difference between the first and the second power level every time a new first and/or second power level is calculated.

16. The test and/or measurement system of claim 8,
wherein the first power measurement unit and the second power measurement unit are configured to calculate the first and the second power level in the logarithmic scale, and wherein the comparison unit is configured to calculate the difference between the first and the second power level in the logarithmic scale.

17. The test and/or measurement system of claim 9,
wherein the control unit is configured to receive the difference between the first and the second power level in the logarithmic;
wherein an output of the control unit is transformed from the logarithmic scale to the linear scale.

18. The test and/or measurement system of claim 1,
wherein the measurement device is a field programmable gate array, FPGA.

19. The test and/or measurement system of claim 1, further comprising:
a first digital signal processor, DSP, which is arranged between the signal generator and the DAC; and/or
a second DSP which is arranged between the ADC and the second power measurement unit.

20. The test and/or measurement system of claim 1,
wherein the signal generator is configured to generate the digital test signal in form of a modulated signal, such as a WiFi, an LTE or a new radio signal.
